(19) United States
(12) Patent Application Publication
(10) Pub. No.: US 2015/0357254 A1
(43) Pub. Date: Dec. 10, 2015

(54) SUBSTRATE FOR ELECTRONIC DEVICE PACKAGE, ELECTRONIC DEVICE PACKAGE, ELECTRONIC DEVICE, AND METHOD OF MANUFACTURING ELECTRONIC DEVICE

(71) Applicant: Seiko Epson Corporation, Tokyo (JP)

(72) Inventor: Masaru MIKAMI, Kochi (JP)

(21) Appl. No.: 14/730,703

(22) Filed: Jun. 4, 2015

(30) Foreign Application Priority Data
Jun. 6, 2014 (JP) 2014-117490
Jun. 6, 2014 (JP) 2014-117491

(51) Int. Cl. H01L 23/053; H01L 21/52; H01L 41/23; H01L 21/48; H01L 23/498; H01L 41/053

(52) U.S. Cl. CPC H01L 23/053; H01L 23/49822; H01L 23/49838; H01L 41/053; H01L 41/23; H01L 21/4807; H01L 21/4857; H01L 21/52

(57) ABSTRACT

A base substrate includes a first layer which is a ceramic layer; a second layer which is disposed on one surface side of the first layer, and contains at least one of a glass layer, a silicon layer, and a quartz layer; and a concave portion that is opened on a side of the second layer opposite to the first layer. In addition, the concave portion is formed through etching.

### BACKGROUND

1. Technical Field

The present invention relates to a substrate for an electronic device package, an electronic device package, an electronic device, and a method of manufacturing the electronic device.

2. Related Art

For example, in JP-A-2008-135727, a cavity type mother substrate which is formed by a ceramic substrate and has a concave portion, is described. In this way, the mother substrate is formed by a ceramic substrate, and thus the following effect can be exhibited. In a state in which the mother substrate is mounted on a circuit substrate (mounting substrate), stress is added to the mother substrate due to a difference in a thermal expansion ratio between the mother substrate and the circuit substrate, but by forming the mother substrate using a ceramic substrate, the mother substrate can be relatively softened, and thus, the stress can be absorbed and relaxed through the mother substrate. For this reason, it is possible to suppress the stress from being transferred to an electronic component which is mounted on the mother substrate, and characteristics of the electronic component from being changed.

In this way, the mother substrate which is formed by a ceramic substrate has an advantage in that a change of the characteristics of the electronic component can be suppressed, but meanwhile, the mother substrate also has the following disadvantage. In a case in which the mother substrate is formed by a ceramic substrate, a stack body of ceramic green sheets is obtained by being calcinated, but the stack body of a green sheet is contracted at the time of calcinating. For this reason, it is difficult to accurately control a shape and a dimension of the mother substrate (particularly, concave portion). In addition, by a deformation due to such contraction, bonding to a lid may be insufficient, and there is also a problem that airtightness of a containment space is decreased.

### SUMMARY

An advantage of some aspects of the invention is to provide a substrate for an electronic device package, an electronic device package, an electronic device, and a method of manufacturing the electronic device in which excellent stress reduction characteristic and excellent dimensional accuracy both can be obtained.

The invention can be implemented as the following application examples.

### APPLICATION EXAMPLE 1

This application example is directed to a substrate for an electronic device package including: a first layer that contains ceramic; and a second layer that is disposed on one surface side of the first layer, contains at least one of glass, silicon, and quartz, as a material thereof, and has a concave portion which is opened on a side opposite to the first layer.

With this configuration, a substrate for an electronic device package in which excellent stress reduction characteristic and excellent dimensional accuracy (particularly, dimensional accuracy of the concave portion) both can be obtained, is obtained.

### APPLICATION EXAMPLE 2

In the substrate for an electronic device package according to the application example, it is preferable that the concave portion is formed by etching the second layer.

With this configuration, it is possible to further increase formation accuracy of the concave portion.

### APPLICATION EXAMPLE 3

In the substrate for an electronic device package according to the application example, it is preferable that the first layer includes a first wiring layer which is electrically connected to an electronic component.

With this configuration, it is possible to easily perform electrical connection of the electronic component.

### APPLICATION EXAMPLE 4

In the substrate for an electronic device package according to the application example, it is preferable that a convex portion which is disposed inside the concave portion and is connected to the electronic component is provided.

With this configuration, it is possible to form a sufficient gap between the electronic component and the substrate for an electronic device package, and to prevent the electronic component and the substrate for an electronic device package from being in contact with each other.

### APPLICATION EXAMPLE 5

In the substrate for an electronic device package according to the application example, it is preferable that the first wiring layer is disposed so as to extend to the convex portion.

With this configuration, it is possible to easily perform electrical connection of the electronic component.

### APPLICATION EXAMPLE 6

In the substrate for an electronic device package according to the application example, it is preferable that the first layer includes a plurality of ceramic layers.

With this configuration, for example, it is possible to suppress a decrease of airtightness caused by vias which are formed in each layer.

### APPLICATION EXAMPLE 7

In the substrate for an electronic device package according to the application example, it is preferable that a second wiring layer is disposed between the plurality of ceramic layers and is electrically connected to the first wiring layer.

With this configuration, it is possible to perform an electrical connection between the respective layers.

### APPLICATION EXAMPLE 8

This application example is directed to an electronic device package including: the substrate for an electronic device package according to the application example described above; and a lid that is bonded to the substrate for an electronic device package so as to close an opening of the concave portion.

With this configuration, an electronic device package in which excellent stress reduction characteristic and excellent dimensional accuracy (particularly, dimensional accuracy of the concave portion) both can be obtained, is obtained.

### APPLICATION EXAMPLE 9

In the electronic device package according to the application example, it is preferable that the second layer includes glass, and the lid and the second layer are bonded together using glass fusion bonding.

With this configuration, it is possible to simply and firmly bond together the substrate for an electronic device package and the lid. In addition, there is provided an electronic device package in which a thermal expansion at the time of bonding is suppressed, and internal stress is low.

### APPLICATION EXAMPLE 10

In the electronic device package according to the application example, it is preferable that the lid includes a lid side concave portion which is connected to the concave portion and is opened on a surface on the second layer side.

With this configuration, it is possible to lower a height (depth) of the concave portion of the substrate for an electronic device package, and formation accuracy of the concave portion is further increased.

### APPLICATION EXAMPLE 11

In the electronic device package according to the application example, it is preferable that the lid side concave portion is formed by etching.

With this configuration, it is possible to further increase formation accuracy of a lid side concave portion.

### APPLICATION EXAMPLE 12

This application example is directed to an electronic device including: the electronic device package according to the application example described above; and an electronic component that is contained in the electronic device package.

With this configuration, an electronic device in which excellent stress reduction characteristic and excellent dimensional accuracy (particularly, dimensional accuracy of the concave portion) both can be obtained, is obtained.

### APPLICATION EXAMPLE 13

This application example is directed to a method of manufacturing an electronic device including: preparing a base substrate that includes a first layer which contains ceramic, and a second layer which is disposed on one surface side of the first layer, contains at least one of glass, silicon, and quartz as a material, and has a concave portion that is opened on a side opposite to the first layer; disposing an electronic component inside the concave portion; and bonding the lid to the base substrate so as to contain the electronic component together with the base substrate.

With this configuration, a method of manufacturing an electronic device in which excellent stress reduction characteristic and excellent dimensional accuracy (particularly, dimensional accuracy of the concave portion) both can be obtained, is obtained.

### APPLICATION EXAMPLE 14

In the method of manufacturing an electronic device according to the application example, it is preferable that the preparing of the base substrate includes forming the concave portion through etching.

With this configuration, it is possible to further increase formation accuracy of the concave portion.

### BRIEF DESCRIPTION OF THE DRAWINGS

The invention will be described with reference to the accompanying drawings, wherein like numbers reference like elements.

FIG. 1 is a plan diagram illustrating an electronic device according to a first embodiment of the invention.

FIG. 2 is a sectional diagram taken along line II-II in FIG. 1.

FIGS. 3A and 3B are plan diagrams illustrating a resonation element which is included in the electronic device of FIG. 1.

FIG. 4 is a sectional diagram illustrating a state in which the electronic device illustrated in FIG. 1 is mounted on a circuit substrate.

FIGS. 5A to 5C are sectional diagrams illustrating a method of manufacturing the electronic device illustrated in FIG. 1.

FIGS. 6A and 6B are sectional diagrams illustrating a method of manufacturing the electronic device illustrated in FIG. 1.

FIGS. 7A to 7C are sectional diagrams illustrating a method of manufacturing the electronic device illustrated in FIG. 1.

FIGS. 8A and 8B are sectional diagrams illustrating a method of manufacturing the electronic device illustrated in FIG. 1.

FIG. 9 is a sectional diagram illustrating an electronic device according to a second embodiment of the invention.

FIGS. 10A to 10C are sectional diagrams illustrating a method of manufacturing a base substrate of the electronic device illustrated in FIG. 9.

FIG. 11 is a sectional diagram illustrating an electronic device according to a third embodiment of the invention.

FIG. 12 is a perspective diagram illustrating a configuration of a personal computer of a mobile type (or notebook type) including an electronic device according to the invention.

FIG. 13 is a perspective diagram illustrating a configuration of a mobile phone (including PHS) including an electronic device according to the invention.

FIG. 14 is a perspective diagram illustrating a configuration of a digital still camera including an electronic device according to the invention.

FIG. 15 is a perspective diagram illustrating a moving object including an electronic device according to the invention.

### DESCRIPTION OF EXEMPLARY EMBODIMENTS

Hereinafter, a substrate for an electronic device package, an electronic device package, an electronic device, and a method of manufacturing the electronic device will be described in detail based on embodiments illustrated in the attached drawings.

### First Embodiment

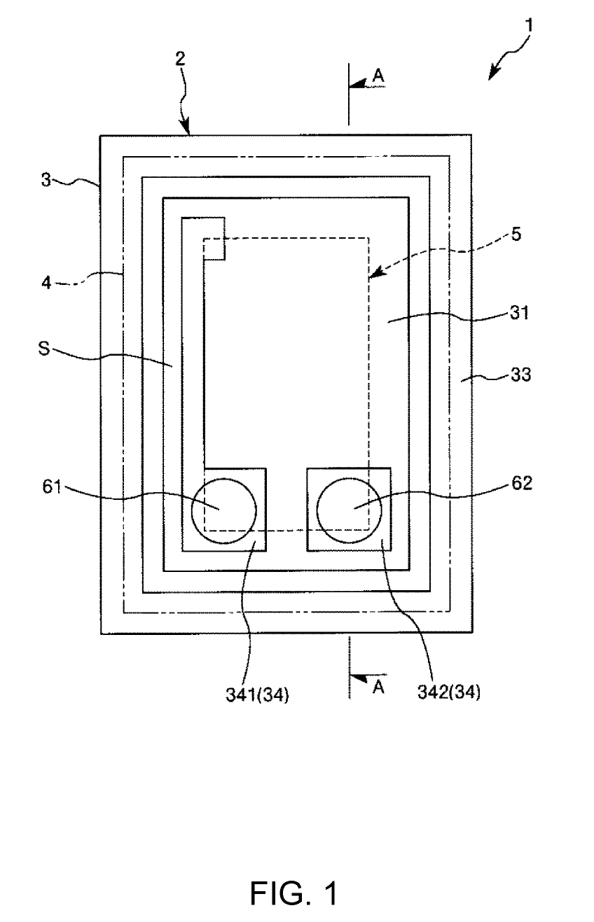

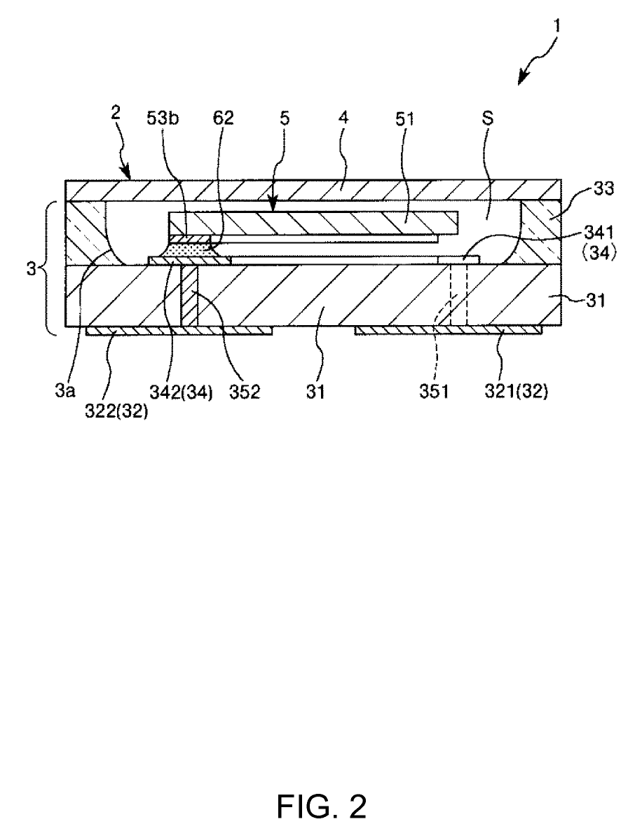

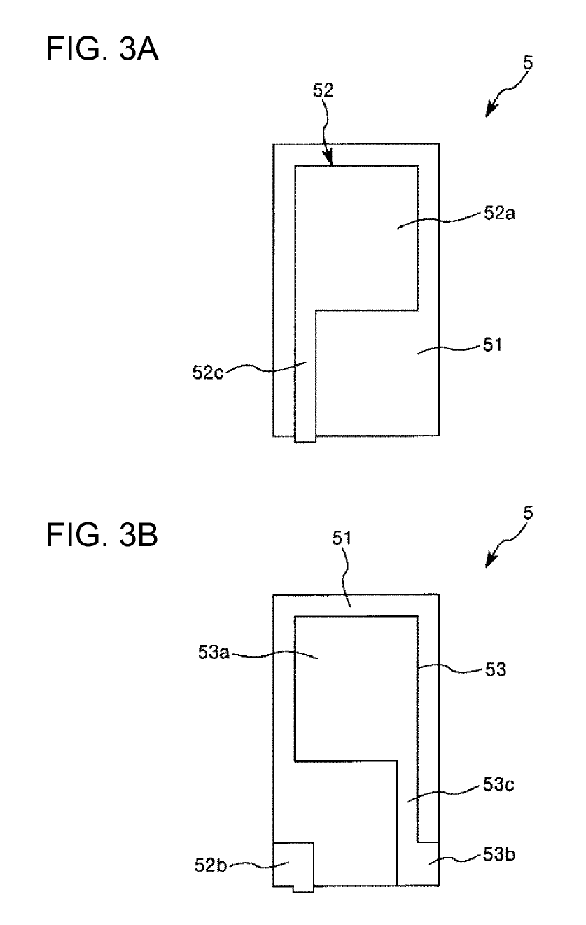

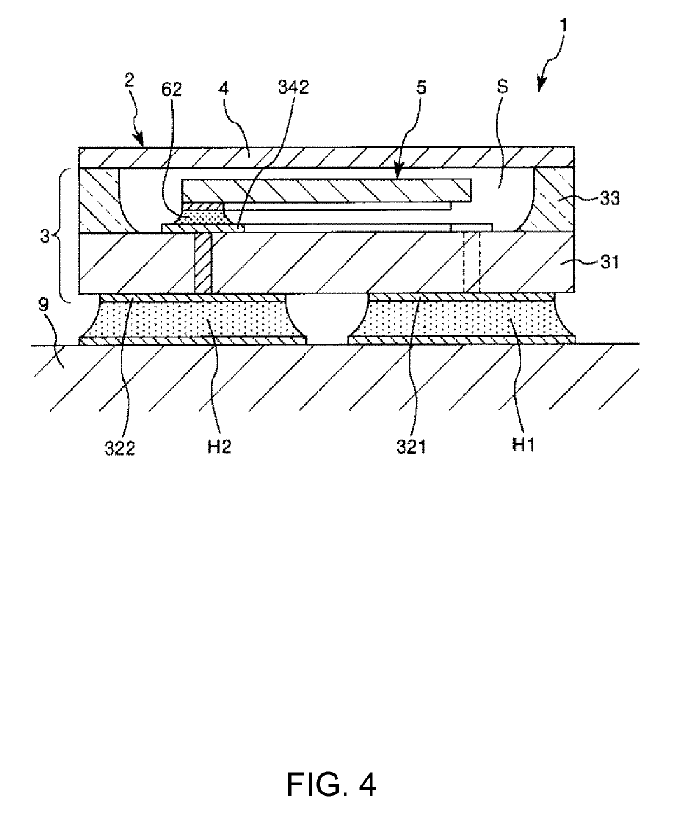

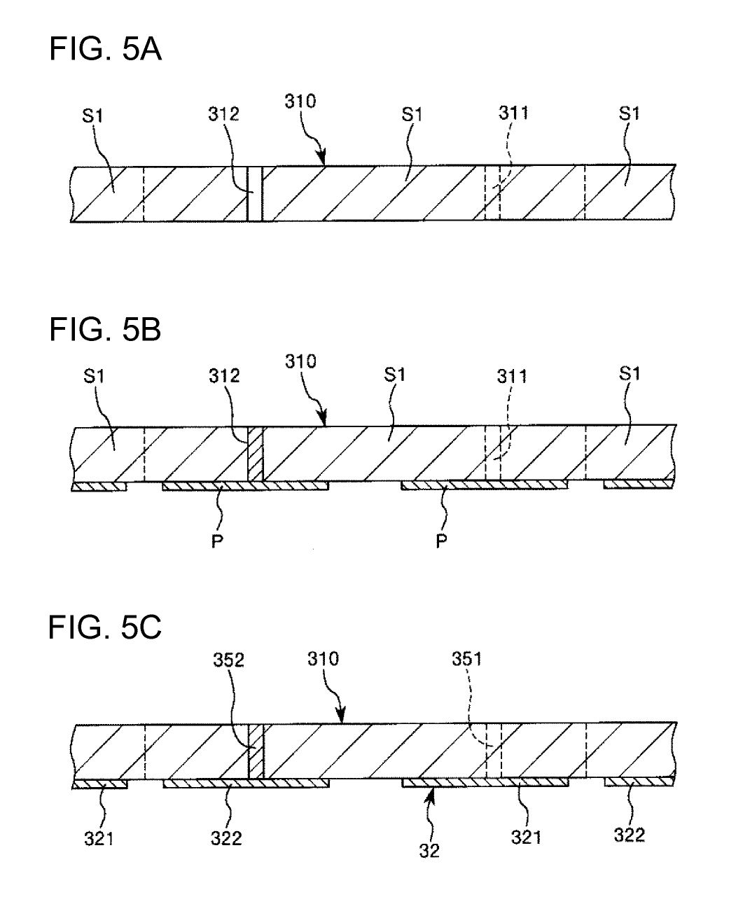

FIG. 1 is a plan diagram illustrating an electronic device according to a first embodiment of the invention. FIG. 2 is a sectional diagram taken along line II-II in FIG. 1. FIGS. 3A and 3B are plan diagrams illustrating a resonation element which is included in the electronic device of FIG. 1. FIG. 4 is a sectional diagram illustrating a state in which the electronic device illustrated in FIG. 1 is mounted on a circuit substrate. FIGS. 5A to 8B are respectively sectional diagrams illustrating a method of manufacturing the electronic device illustrated in FIG. 1. In the following description, the front side of a paper surface of FIG. 1 and an upper portion of FIG. 2 are referred to as “upper”, and the rear side of the paper surface of FIG. 1 and a lower portion of FIG. 2 are referred to as “lower”.

### Electronic Device

As illustrated in FIG. 1 and FIG. 2, an electronic device 1 which functions as a resonator includes a package (electronic device package) 2, and a resonation element (electronic component) 5 which is contained in the package 2. In addition, the package 2 includes a base substrate (substrate for an electronic device package) 3 of a cavity shape having a concave portion 3a, and a lid 4 which is bonded to the base substrate 3 so as to close an opening of the concave portion 3a.

### Resonation Element

As illustrated in FIGS. 3A and 3B, the resonation element 5 includes a quartz crystal substrate 51 of a rectangular plate shape in a planar view, and a pair of conductor layers 52 and 53 which is formed on a surface of the quartz crystal substrate 51. FIG. 3A is a plan diagram in which the resonation element 5 is viewed from top, and FIG. 3B is a transparent diagram in which the resonation element 5 is viewed from top.

The quartz crystal substrate 51 is a quartz crystal element substrate which is cut out at a cut angle called an AT-cut. In addition, the conductor layer 52 includes an excitation electrode 52a which is formed on an upper surface of the quartz crystal substrate 51, a bonding pad 52b which is formed on a lower surface of the quartz crystal substrate 51, and a wire 52c which electrically connects the excitation electrode 52a and the bonding pad 52b. In the same manner, the conductor layer 53 includes an excitation electrode 53a which is formed on a lower surface of the quartz crystal substrate 51, a bonding pad 53b which is formed on a lower surface of the quartz crystal substrate 51, and a wire 53c which electrically connects the excitation electrode 53a and the bonding pad 53b. In the resonation element 5 having such a configuration, an alternate voltage is applied between the excitation electrodes 52a and 53a, and thereby a resonation area which is interposed between the excitation electrodes 52a and 53a performs thickness-shearing resonation.

As described above, description with regard to the resonation element 5 is made, but a configuration of the resonation element 5 is not limited to the above-described configuration. For example, the resonation element 5 may be a mesa type AT-cut quartz crystal resonation element with a thick resonation area, or in contrast, may be a reverse mesa type AT-cut quartz crystal resonation element with a thin resonation area. In addition, instead of an AT-cut, the quartz crystal substrate 51 of a BT-cut may be used. In addition, the resonation element 5 may be a tuning fork type resonation element in which a pair of resonating arms performs a flexural vibration. In addition, instead of the quartz crystal substrate 51, an oxide substrate which is formed of aluminum nitride (AlN), lithium niobate (LiNbO₃), lithium tantalate (LiTaO₃), lead zirconate titanate (PZT), lithium tetraborate (Li₂B₄O₇), langasite (La₃Ga₅SiO₁₄) or the like, a stack piezoelectric substrate which is configured by stacking a piezoelectric material such as aluminum nitride, or tantalum pentoxide (Ta₂O₅) on a glass substrate, or a piezoelectric ceramic substrate may be used. In addition, the resonation element may be a non-piezoelectric resonation element which is excited by disposing a piezoelectric element on a silicon substrate and by expanding and contracting the piezoelectric element according to a conduction.

### Package

As illustrated in FIG. 1 and FIG. 2, the package 2 includes the base substrate 3 having the concave portion 3a whose upper surface is open, and the lid 4 which closes the opening of the concave portion 3a. In the package 2, the inside of the concave portion 3a which is closed by the lid 4 functions as a containment space S which contains the resonation element 5 described above.

As illustrated in FIG. 2, the base substrate 3 includes a first layer 31 which configures a bottom portion, a second layer 33 which is disposed (stacked) on an upper surface (one surface) side of the first layer 31 and configures a side wall, a wiring layer 32 which is disposed on a lower surface of the first layer 31, and a wiring layer 34 which is disposed on an upper surface of the first layer 31.

The first layer 31 is a ceramic layer. The first layer 31 is obtained by performing calcination processing of ceramic green sheets which are obtained by forming, in a sheet shape, a mixture of, for example, ceramic powder, glass powder (glass components), and binder. The first layer 31 may be a so-called low temperature calcination ceramic layer. In this way, by containing glass components in the first layer 31, the first layer 31 can be softened, and specifically, the Young's modulus of the first layer 31 can be lower than that of the second layer 33. A ceramic material of the first layer 31 is not particularly limited, but for example, various ceramics, such as oxide ceramic such as alumina, silica, titania, or zirconia; nitride-based ceramic such as silicon nitride, aluminum nitride, or titanium nitride; or carbide-based ceramic such as silicon carbide can be used as the ceramic material of the first layer 31. In addition, the glass components are not particularly limited, but for example, borosilicate glass, quartz glass, soda glass (soda lime glass), potassium glass, or the like can be used as the glass components.

Then, the second layer 33 is stacked on the upper surface of the first layer 31. The second layer 33 is a glass layer which is configured of a glass material which is used as a main material. The glass material of the second layer 33 is not particularly limited, but for example, borosilicate glass, quartz glass, soda glass (soda lime glass), potassium glass, alkali-free glass, or the like can be used as the glass material. A method of bonding the first layer 31 and the second layer 33 is not particularly limited, but for example, fusion bonding performed by melting glass, and bonding (surface activation bonding) using a metal film, or the like can be used as the method.

In addition, the wiring layer 32 with conductivity is disposed on a lower surface of the first layer 31, and the wiring layer 32 includes a pair of external connection terminals 321 and 322. In addition, the wiring layer 34 with conductivity is disposed on an upper surface (between the first layer 31 and the second layer 33) of the first layer 31, and the wiring layer 34 includes a pair of internal connection terminals 341 and 342. In addition, the external connection terminal 321 and the internal connection terminal 341 are electrically connected together through a via (via electrode) 351 which passes through the first layer 31, and the external connection terminal 322 and the internal connection terminal 342 are electrically connected together through a via 352 which passes through the first layer 31. Materials configuring the external connection terminals 321 and 322, the internal connection terminals 341 and 342, and the vias 351 and 352 are not particularly limited, as long as the materials are conductive, and, for example, a metal material, such as, gold (Au), silver (Ag), copper (Cu), platinum (Pt), aluminum (Al), chromium (Cr), nickel (Ni), molybdenum (Mo), tungsten (W), or the like can be used as the material.

The concave portion 3a which is opened on the upper surface (upper surface (a surface on a side opposite to the first layer 31) of the second layer 33) is provided on the base substrate 3 having such a configuration, and the resonation element 5 is contained in the concave portion 3a. In addition, the concave portion 3a is formed by a through-hole which passes through the second layer 33, a side surface of the concave portion 3a is configured of an inner periphery surface of the through-hole, and a bottom surface of the concave portion 3a is configured of the upper surface of the first layer 31. As a result, the concave portion 3a is obtained by forming a through-hole using etching processing or the like in the second layer 33 which is a glass layer, and thus it is easy to form the concave portion 3a. In addition, the internal connection terminals 341 and 342 are positioned inside the concave portion 3a. In other words, the internal connection terminals 341 and 342 are exposed to the outside from the concave portion 3a. Then, the resonation element 5 is fixed to the base substrate 3 (bottom surface of the concave portion 3a) with conductive adhesives 61 and 62, and the internal connection terminals 341 and 342 and the bonding pads 52b and 53b are electrically connected to each other.

The base substrate 3 is described above. Here, a thickness of the first layer 31 is not particularly limited, and for example, can be set to be equal to or more than 200 μm and equal to or less than 300 μm. In addition, a thickness of the second layer 33 is not particularly limited, and, for example, can be set to be equal to or more than 100 μm and equal to or less than 200 μm.

The lid 4 is formed in a flat plate shape, and is bonded on an upper surface of the base substrate 3 so as to close the opening of the concave portion 3a. By doing this, an airtight containment space S is formed in the inside of the base substrate 3, and the resonation element 5 is contained in the containment space S. In other words, the lid 4 is bonded to the base substrate 3 so as to contain the resonation element 5, together with the base substrate 3. The environment in the containment space S is also changed due to a configuration of the resonation element 5, but, for example, may be in a decompressed state (preferably, vacuum state), or inert gas, such as nitrogen, helium, argon, or the like may be sealed in the containment space.

A configuration material of the lid 4 is not particularly limited, and, for example, various ceramics, various metals, various glasses, quartz, silicon, or the like can be used as the configuration material. In addition, a method of bonding the lid 4 and the base substrate 3 is changed depending on a configuration material of the lid 4, and, for example, may be bonded through an adhesive, low-melting-point glass, or a bonding layer such as a metal layer, and may be bonded through an anodic bonding, surface activation bonding, fusion bonding, or the like.

However, it is preferable that glass listed among the above-described materials is configured as a main material of the lid 4, and furthermore, it is preferable that the lid 4 is bonded to the base substrate 3 through glass fusion bonding. By doing this, the lid 4 and the second layer 33 can be configured of glass as main materials, and thus it is possible to reduce a thermal expansion difference between the lid 4 and the second layer 33, and to provide the package 2 to which thermal stress is difficult to be added. In addition, it is possible to increase affinity of the lid 4 and the second layer 33 to each other, and to more firmly bond the lid 4 to the second layer 33. In addition, the lid 4 can be directly bonded to the base substrate 3, and thus it is possible to reduce cost.

The electronic device 1 is described above. The electronic device 1 uses the base substrate 3 which is a stack body of a ceramic layer and a glass layer for the package 2, and thus it is possible to exhibit the following effects. As a first effect, an excellent stress reduction (absorption) function can be exhibited. Specifically, as described in FIG. 4, in a state in which the electronic device 1 is mounted on a circuit substrate (printed wiring substrate) 9 using solders H1 and H2, a thermal expansion ratios between the circuit substrate 9 and the package 2 are different, and thus thermal stress is added to the base substrate 3 (particularly, the first layer 31). However, the first layer 31 is configured of a ceramic layer which is relatively soft, and thus the first layer 31 can reduce and absorb the thermal stress. For this reason, it is possible to suppress the thermal stress from being transferred to the resonation element 5 through the base substrate 3, and to prevent or reduce a change in resonation characteristics (frequency characteristic) of the resonation element 5. In addition, as a second effect, excellent dimensional accuracy (processability) can be obtained. Specifically, the concave portion 3a is formed in the base substrate 3, but the concave portion 3a is formed by a through-hole which passes through the second layer 33, as described above. The second layer 33 is configured of a glass layer, and, for example, patterning processing is easily performed using a photolithography technique and an etching technique, and thus it is possible to form the concave portion 3a having simple and high dimensional accuracy. As described above, according to the base substrate 3 which is a stack body of a ceramic layer and a glass layer, it is possible to obtain both excellent stress reduction characteristic and excellent dimensional accuracy (processing characteristic).

For example, in a case in which the base substrate 3 is configured of a ceramic layer in the same manner as in the related art, the first effect can also be exhibited, but the second effect cannot be exhibited (refer to “BACKGROUND” of the specification). In contrast to this, in a case in which the base substrate 3 is configured of a glass layer, the second effect can also be exhibited, but the first effect cannot be exhibited. That is, in a case in which the base substrate 3 is configured of a glass layer, the base substrate 3 is excessively hardened, the thermal stress cannot be reduced and absorbed, and changes in the resonation characteristics of the resonation element 5 cannot be suppressed. In addition, there is a problem in which the package 2 is broken (crack occurs), or according to this, air tightness of the containment space S is decreased, or the like.

In addition, in the base substrate 3 according to the present embodiment, the second layer 33 is configured of glass, but as a configuration material of the second layer 33, instead of glass, silicon (monocrystalline silicon, polycrystalline silicon, amorphous silicon) or quartz may be used. In this way, even if the second layer 33 is configured of silicon or quartz, the same effect (that is, excellent dimensional accuracy) as in a case of being configured of glass can be exhibited. In addition, the second layer 33 may be configured by stacking two or more layers which are selected from a glass layer, a silicon layer, and a quartz layer. In a case in which the second layer 33 is configured of silicon, the first layer 31 and the second layer 33 can be bonded by, for example, anodic bonding.

### Method of Manufacturing Electronic Device

Next, a method of manufacturing the electronic device 1 will be described.

A method of manufacturing the electronic device 1 includes a wiring layer forming process in which a first layer 310 that is configured of a ceramic layer and includes a plurality of singulation areas S1 is prepared, and the wiring layer 32 is formed on a lower surface of the first layer 310, a second layer forming process in which a second layer 330 that is a glass layer is formed on an upper surface of the first layer 310, a concave portion forming process in which a plurality of concave portions 3a that is opened on an upper surface of the second layer 330 is formed by etching, an internal wiring layer forming process in which the wiring layer 34 is formed inside the concave portion 3a, a resonation element mounting process in which the resonation element 5 is mounted inside the concave portion 3a, a lid bonding process in which the lid 4 is bonded, and a singulation process in which singulation is performed for each singulation area 51.

### Wiring Layer Forming Process

First, as illustrated in FIG. 5A, the first layer 310 which includes the plurality of singulation areas 51 in a matrix is prepared. The first layer 310 is an uncalcinated ceramic layer, and, for example, is ceramic green sheets which are obtained by forming a mixture of alumina powder, borosilicate glass powder, and organic resin binder in a sheet shape, and furthermore, by forming through-holes 311 and 312 for vias 351 and 352 using punching or the like. Next, as illustrated in FIG. 5B, a conductor pattern P which is configured with a conductor paste including a high melting point metal such as tungsten, or molybdenum is disposed in accordance with the shapes of the vias 351 and 352 and the external connection terminals 321 and 322, inside the through-holes 311 and 312 of the first layer 310 and on the lower surface of the first layer 310. Next, the first layer 310 is calcinated and thereafter, the conductor pattern P is coated with gold and thus as illustrated in FIG. 5C, the vias 351 and 352 and the external connection terminals 321 and 322 (wiring layer 32) are formed on the first layer 310 which is configured of a calcinated ceramic layer.

### Second Layer Forming Process

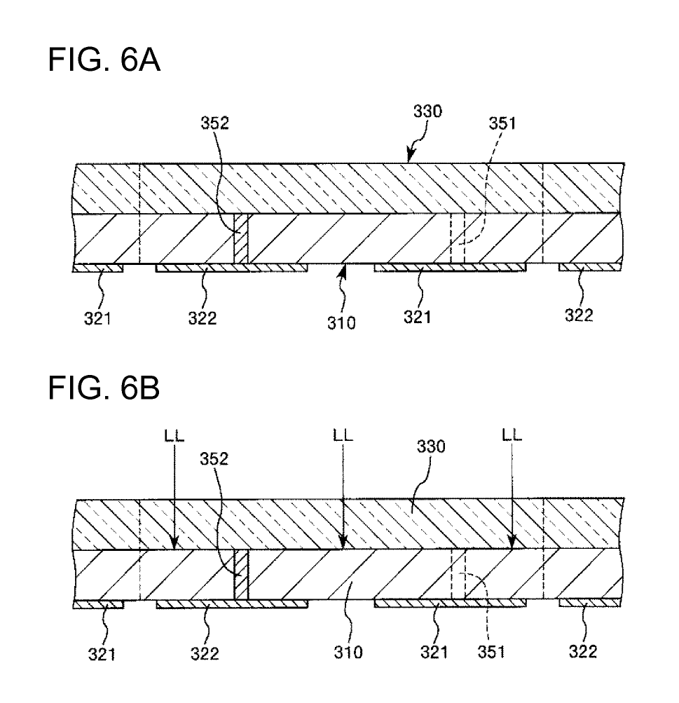

Next, as illustrated in FIG. 6A, the second layer 330, which is configured of a glass material, of a plate shape is prepared, and the second layer 330 is stacked on the upper surface of the first layer 310. Next, as illustrated in FIG. 6B, a boundary between the first layer 310 and the second layer 330 is irradiated with laser LL under pressure, and glass (glass components contained in the first and second layers 310 and 330) in the boundary and in the periphery thereof is melted. Thus, the first layer 310 and the second layer 330 are bonded together by fusion bonding. According to such a method, it is possible to simply bond together the first layer 310 and the second layer 330. Particularly, the first layer 310 contains glass components, and thus it is possible to increase affinity of the first layer 310 and the second layer 330, and to more firmly bond the first layer 310 and the second layer 330. In addition, since the boundary is locally irradiated with the laser LL, it is possible to suppress a temperature increase in the first layer 310 and the second layer 330, and thus it is possible to decrease thermal expansion in the first layer 310 and the second layer 330 at the time of bonding. For this reason, it is possible to obtain the base substrate 3 in which residual stress is reduced, and it is possible to more effectively suppress peeling of the second layer 330, or occurrence of cracking.

Here, a glass transition point (Tg) of the second layer 330 is not particularly limited, but it is preferable that the glass transition point is equal to or lower than 600° C. By doing this, it is possible to melt the glass of the second layer 330 at a sufficiently low temperature, the temperature increase (thermal expansion) of the first and second layers 310 and 330 at the time of laser radiation is effectively suppressed, and residual stress is decreased more than usual.

The second layer 330 which is thicker than a designed value is prepared and is bonded to the first layer 310. Thereafter, the second layer 330 may be thinned to the designed value using grinding, etching, or the like. According to this method, strength of the second layer 330 can be increased, and thus handling properties are improved, and it is possible to effectively suppress breakage or the like of the second layer 330 during working.

### Concave Portion Forming Process

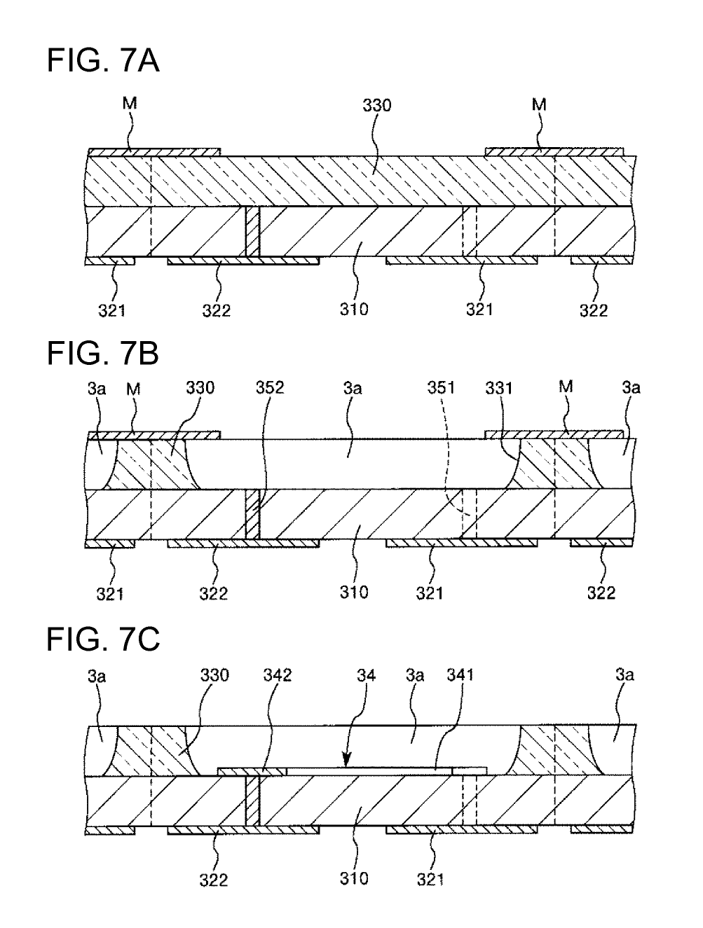

Next, the concave portion 3a is formed in each singulation area S1. Specifically, to begin with, as illustrated in FIG. 7A, a mask M having an opening corresponding to the concave portion 3a is formed on the upper surface of the second layer 330. Next, as illustrated in FIG. 7B, wet etching is performed through the mask M, and the through-hole 331 which passes through the second layer 330 is formed. By doing this, the concave portion 3a is formed. At this time, the through-hole 331 is formed such that upper ends of the vias 351 and 352 are exposed in the through-holes. In this way, by using etching processing, it is possible to simply and accurately form the concave portion 3a which has desired dimensions. Since the second layer 330 is isotropically etched during the wet etching, a side surface of the concave portion 3a which is formed becomes a curved concave surface. Thus, it is possible to secure a wide bonding area for the first layer 310 and the second layer 330, to increase the volume of the concave portion 3a, and to reduce a decrease in mechanical strength due to the formation of the concave portion 3a. An etching method is not limited to the wet etching, and, for example, dry etching may be used for the etching method. The concave portion 3a which is formed by dry etching has a side surface which is substantially vertically steep, unlike in a case of performing wet etching described above.

### Internal Wiring Layer Forming Process

Next, as illustrated in FIG. 7C, the internal connection terminals 341 and 342 (wiring layer 34) are formed on a bottom surface (upper surface of the first layer 310) of the concave portion 3a. Formation of the internal connection terminals 341 and 342 is not particularly limited, but, for example, a metal layer is formed on the bottom surface of the concave portion 3a, the metal layer is patterned using a photolithography technique and an etching technique, and thereby the internal connection terminals 341 and 342 can be formed.

### Resonation Element Mounting Process and Lid Bonding Process

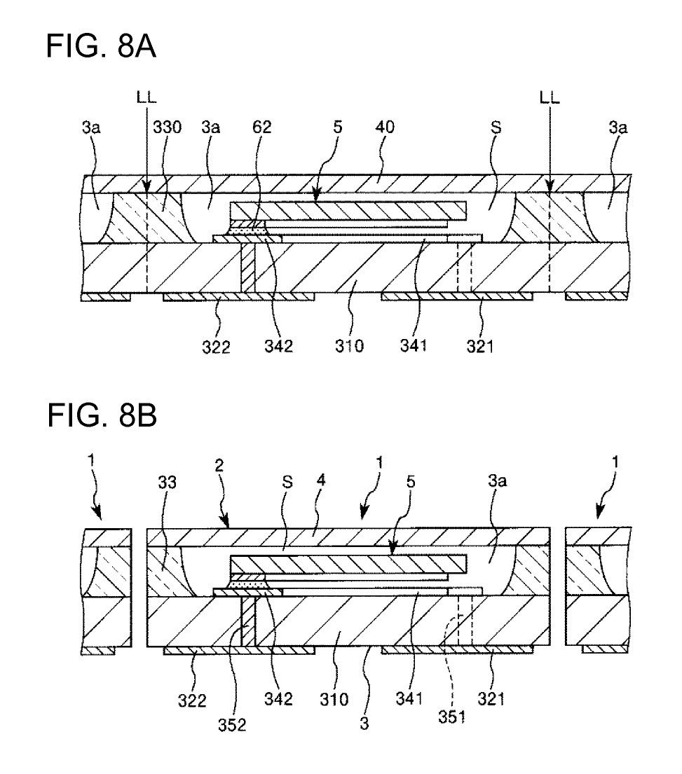

Next, as illustrated in FIG. 8A, the resonation element 5 is mounted inside each of the concave portions 3a using the conductive adhesives 61 and 62 (the conductive adhesive 61 is not illustrated), and thereafter, the lid substrate 40 in which a plurality of lids 4 is integrally included is bonded to the upper surface of the second layer 330, and the opening of the concave portion 3a is closed. For example, in a case in which the lid substrate 40 is configured of a glass substrate, in a state in which the lid substrate 40 is stacked on the second layer 330 of the base substrate 3, a boundary between the lid substrate 40 and the second layer 330 is irradiated with the laser LL, glass in the boundary and in the periphery thereof is melted, and the lid substrate 40 and the second layer 330 are bonded together by fusion-bonding the glass. According to this method, it is possible to simply bond the lid substrate 40 to the base substrate 3. Particularly, since the lid substrate 40 and the second layer 330 are both glass, it is possible to increase affinity of the lid substrate 40 and the second layer 330, and to more firmly bond together the lid substrate 40 and the second layer 330. In addition, since the boundary is locally irradiated with the laser LL, it is possible to suppress an excessive temperature increase of the lid 4 or the base substrate 3, and to decrease thermal expansion at the time of bonding. Therefore, it is possible to obtain the package 2 in which residual stress is reduced, and it is possible to more effectively suppress peeling of the lid 4, or occurrence of cracking. In addition, it is also possible to suppress peeling of the first layer 310 and the second layer 330 at the time of temperature increase.

While not being illustrated, a sealing hole which links the inside and outside of the containment space S is formed in the first layer 310, the lid substrate 40 is bonded to the second layer 330, thereafter, the inside of the containment space S is decompressed through the sealing hole, and the sealing hole is sealed with Au-Ge-based alloy or the like. Therefore it is possible to maintain the inside of the containment space S in a decompressed state.

### Singulation Process

Next, the singulation areas S1 are singulated by cutting means such as a dicing saw, and thus, as illustrated in FIG. 8B, a plurality of electronic devices 1 is obtained. In this way, the plurality of electronic devices 1 is formed as one piece and then is singulated, and thus manufacturing efficiency of the electronic device 1 is increased. However, a sequence of the singulation process is not limited to the sequence described above, and, for example, the singulation process may be performed earlier than any one of the internal wiring layer forming process, the resonation element mounting process, and the lid bonding process.

As described above, a method of manufacturing the electronic device 1 is described. According to the manufacturing method, it is possible to simply manufacture the electronic device 1 (base substrate 3) in which excellent stress reduction characteristic and excellent dimensional accuracy both can be obtained.

### Second Embodiment

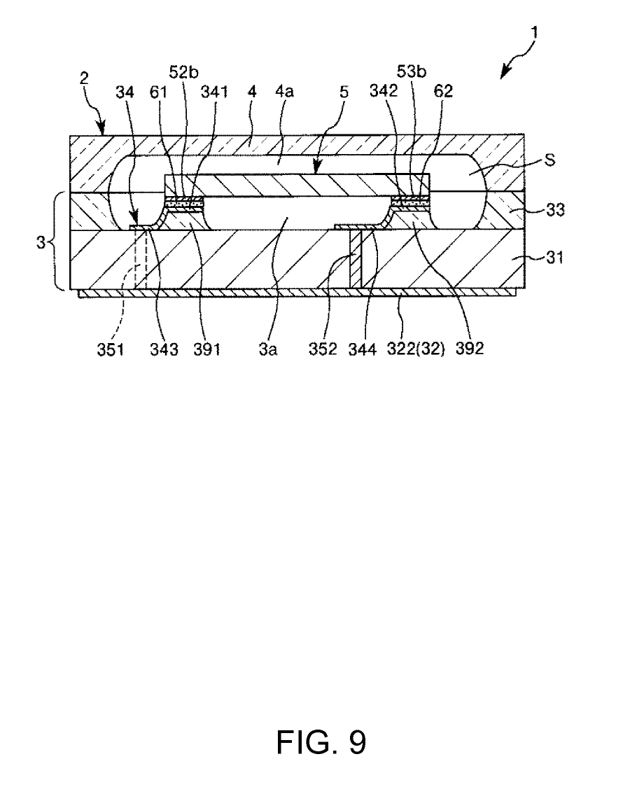

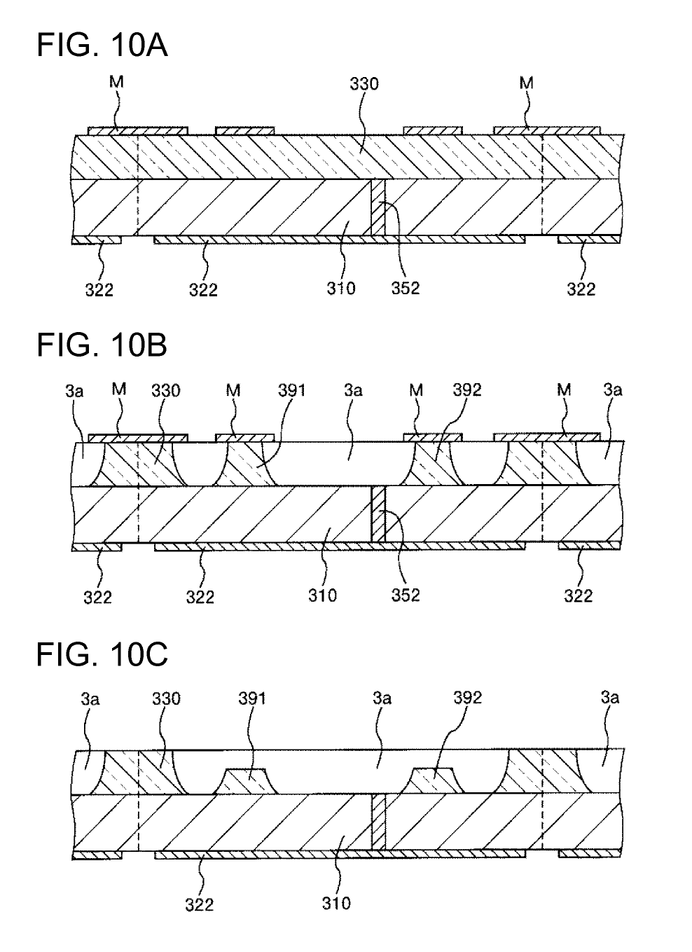

FIG. 9 is a sectional diagram illustrating an electronic device according to a second embodiment of the invention. FIGS. 10A to 10C are sectional diagrams illustrating methods of manufacturing a base substrate of the electronic device illustrated in FIG. 9.

Hereinafter, an electronic device according to the second embodiment of the invention will be described, but points of difference from the embodiment described above will be mainly described, and description which is redundant will be omitted.

The electronic device according to the second embodiment has a configuration of a package which is different from that of the first embodiment described above, however, the other configurations are the same. The same symbols or reference numerals will be attached to the same configurations as those of the first embodiment described above.

As illustrated in FIG. 9, in the base substrate 3 according to the present embodiment, a pair of convex portions 391 and 392 which protrudes from a bottom surface of the concave portion 3a is provided inside the concave portion 3a. Then, the resonation element 5 is fixed to the convex portions 391 and 392 through the conductive adhesives 61 and 62. In this way, the convex portions 391 and 392 are provided and the resonation element 5 is fixed to the convex portions 391 and 392, and thus, it is possible to form a sufficient gap between the resonation element 5 and a bottom surface of the concave portion 3a, and to reduce unintended contact between the resonation element 5 and the base substrate 3.

In addition, the wiring layer 34 is disposed extending from an upper surface of the first layer 31 to upper surfaces of the convex portions 391 and 392, and is electrically connected to the resonation element 5 through the conductive adhesives 61 and 62. Specifically, the wiring layer 34 includes the internal connection terminal 341 which is disposed on an upper surface of the convex portion 391, the internal connection terminal 342 which is disposed on an upper surface of the convex portion 392, a wire 343 which electrically connects the via 351 and the internal connection terminal 341, and a wire 344 which electrically connects the via 352 and the internal connection terminal 342. Then, the internal connection terminal 341 is connected to a bonding pad 52b of the resonation element 5 through the conductive adhesive 61, and the internal connection terminal 342 is connected to a bonding pad 53b through the conductive adhesive 62.

The convex portions 391 and 392 can be formed by the same process as that of forming the concave portion 3a. That is, as illustrated in FIG. 10A, to begin with, masks M corresponding to shapes of the concave portion 3a and the convex portions 391 and 392 are formed in an upper surface of the second layer 330. Next, as illustrated in FIG. 10B, wet etching is performed through the masks M, and thus the concave portion 3a and the convex portions 391 and 392 are simultaneously formed. Next, only the convex portions 391 and 392 are etched from an upper surface side, and thus, as illustrated in FIG. 10C, heights of the convex portions 391 and 392 are adjusted. According to this method, it is possible to simply and accurately form the convex portions 391 and 392.

Meanwhile, the lid 4 has a cavity shape including the concave portion 4a which is opened on the lower surface, and is bonded to the base substrate 3 such that the concave portion 4a is linked (connected) to the concave portion 3a. That is, the containment space S is formed of the concave portion 3a and the concave portion 4a, and the resonation element 5 is contained in the containment space S. In this way, the concave portion 4a is provided in the lid 4, and thus, it is possible to make the concave portion 3a lower by that amount. For this reason, it is possible to reduce the amount of etching performed at the time of forming the concave portion 3a, and to form the concave portion 3a with higher dimensional accuracy. A method of forming the concave portion 4a is not particularly limited, but it is preferable that the concave portion 4a is formed by etching (wet etching, dry etching) process. By doing this, it is possible to form the concave portion 4a with excellent dimensional accuracy, in the same manner as in the concave portion 3a.

Also by the second embodiment described above, the same effects as those of the first embodiment described above can be exhibited.

In the present embodiment, the upper surfaces of the convex portions 391 and 392 are positioned on a side lower than the upper surface of the second layer 33, but the heights of the convex portions 391 and 392 are not limited to this, and the upper surfaces of the convex portions 391 and 392 may be the same surface as the upper surface of the second layer 33.

### Third Embodiment

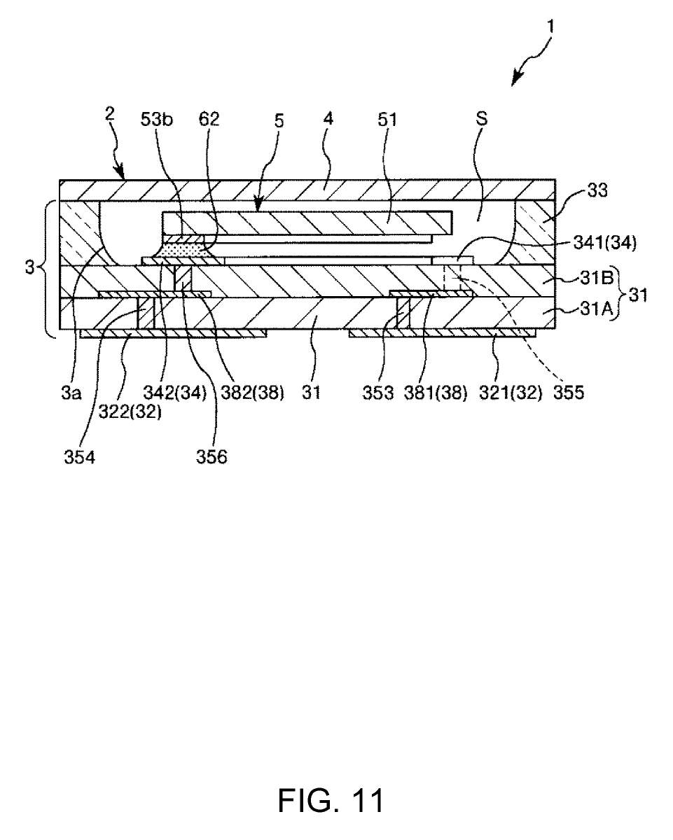

FIG. 11 is a sectional diagram illustrating an electronic device according to a third embodiment of the invention.

Hereinafter, an electronic device according to the third embodiment of the invention will be described, but points of difference from the embodiments described above will be mainly described, and description which is redundant will be omitted.

The electronic device according to the third embodiment has a configuration of a base substrate which is different from the first embodiment described above, however, the other configurations are the same. The same symbols or reference numerals will be attached to the same configurations as those of the embodiments described above.

As illustrated in FIG. 11, the base substrate 3 according to the present embodiment is configured of a stack body in which the first layer 31 is configured of two stacked ceramic layers 31A and 31B. In addition, an internal wiring layer 38 is provided between the ceramic layers 31A and 31B. The internal wiring layer 38 includes a wire 381 which connects the internal connection terminal 341 and the external connection terminal 321, and a wire 382 which connects the internal connection terminal 342 and the external connection terminal 322.

The external connection terminal 321 and the wire 381 are electrically connected together through a via 353 which is provided so as to pass through the ceramic layer 31A, and the internal connection terminal 341 and the wire 381 are electrically connected together through a via 355 which is provided so as to pass through the ceramic layer 31B. In addition, the vias 353 and 355 are disposed in a deviated manner so as not to overlap each other in a planar view. In the same manner, the external connection terminal 322 and the wire 382 are electrically connected together through a via 354 which is provided so as to pass through the ceramic layer 31A, and the internal connection terminal 342 and the wire 382 are electrically connected together through a via 356 which is provided so as to pass through the ceramic layer 31B. In addition, the vias 354 and 356 are disposed in a deviated manner so as not to overlap each other in a planar view. Because both the vias 353 and 355 are disposed in a deviated manner, and the vias 354 and 356 are disposed in a deviated manner, it is thus possible to more effectively prevent the inside and outside of the containment space S from being linked together through the vias 353 to 356, and to increase airtightness of the containment space S.

Also by the third embodiment described above, the same effects as those of the first embodiment described above can be exhibited.

The present embodiment has a configuration in which the first layer 31 is configured of the stacked two layers of the ceramic layers 31A and 31B, but the number of ceramic layers included in the first layer 31 is not limited thereto, and three layers or more may be used.

Next, an electronic apparatus including the electronic device 1 will be described.

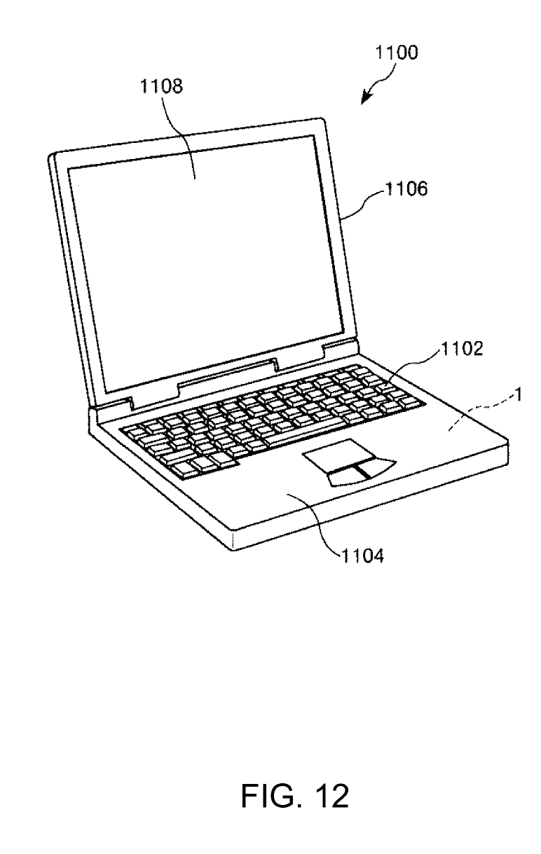

FIG. 12 is a perspective diagram illustrating a configuration of a personal computer of a mobile type (or notebook type) including an electronic device according to the invention. In this figure, a personal computer 1100 is configured of a body unit 1104 including a key board 1102, and a display unit 1106 including a display portion 1108. The display unit 1106 is supported so as to be able to rotate through a hinge structure with respect to the body unit 1104. The electronic device 1 is embedded in the personal computer 1100 as a resonator.

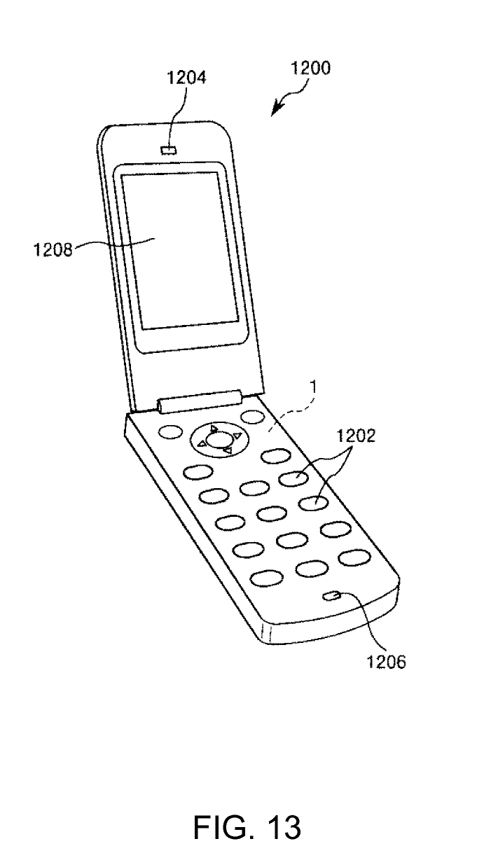

FIG. 13 is a perspective diagram illustrating a configuration of a mobile phone (including PHS) including an electronic device according to the invention. In this figure, a mobile phone 1200 includes a plurality of operation buttons 1202, a voice receiving hole 1204, and a voice transmitting hole 1206. A display portion 1208 is disposed between the operation buttons 1202 and the voice receiving hole 1204. The electronic device 1 is embedded in the mobile phone 1200 as a resonator.

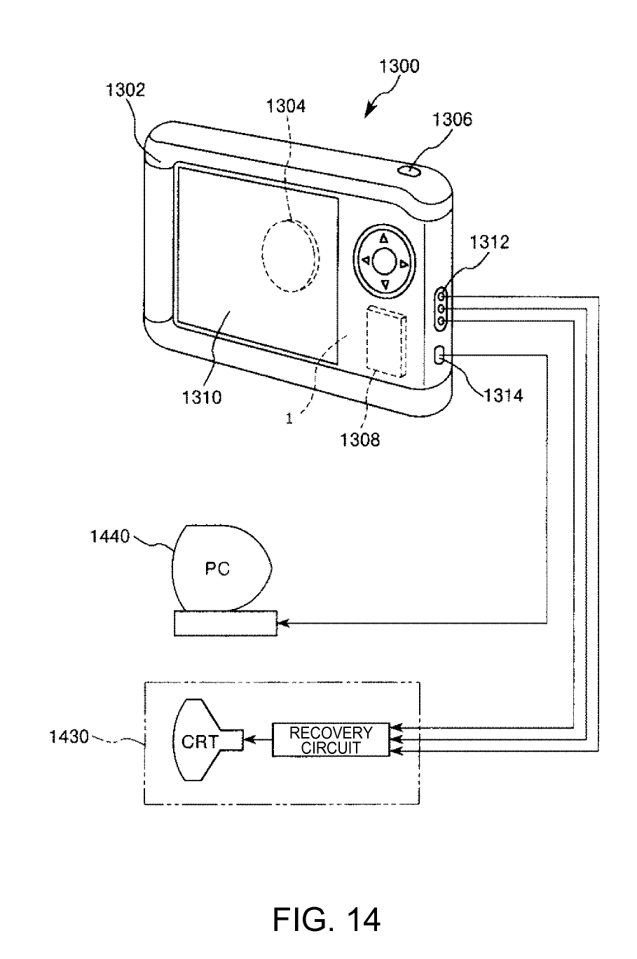

FIG. 14 is a perspective diagram illustrating a configuration of a digital still camera including an electronic device according to the invention. In this figure, a connection to an external apparatus is also simply illustrated. Here, a normal camera exposes a silver photographic film using an optical image of a subject. In contrast to this, a digital still camera 1300 performs a photoelectric conversion of the optical image of the subject using an imaging device such as a charge coupled device (CCD), and generates an imaging signal (image signal).

A display portion 1310 is provided on a rear surface of a case (body) 1302 of the digital still camera 1300, and is configured to perform display based on an imaging signal of the CCD. The display portion functions as a finder which displays a subject as an electronic image. In addition, alight receiving unit 1304 which includes an optical lens (imaging optical system), a CCD, or the like is provided on a front surface side (a back surface side in the figure) of the case 1302.

If a photographer checks a subject image which is displayed on the display portion and pushes a shutter button 1306, an imaging signal of the CCD at that time is transferred to a memory 1308 and is stored there. In addition, for the digital still camera 1300, a video signal output terminal 1312, and an input and output terminal 1314 for data communication are provided on a side surface of a case 1302. Then, as illustrated, a television monitor 1430 is connected to the video signal output terminal 1312, and a personal computer 1440 is connected to the input and output terminal 1314 for data communication, as necessary. Furthermore, the digital still camera 1300 is configured such that an imaging signal which is stored in the memory 1308 is output to the television monitor 1430 or the personal computer 1440 through a predetermined operation. The electronic device 1 is embedded in the digital still camera 1300 as a resonator.

In addition to the personal computer (mobile type personal computer) of FIG. 12, the mobile phone of FIG. 13, and the digital still camera of FIG. 14, an electronic apparatus including the electronic device can also be applied to, for example, an ink jet type ejecting device (for example, ink jet printer), a laptop type personal computer, a television, a video camera, a video tape recorder, a car navigation device, a pager, an electronic notebook (including a communication function), an electronic dictionary, an electronic calculator, an electronic game machine, a word processor, a workstation, a videophone, security television monitor, electronic binoculars, a POS terminal, a medical apparatus (for example, an electronic thermometer, a blood pressure monitor, a blood glucose meter, an electrocardiogram measuring device, an ultrasonic diagnostic device, an electronic endoscope), a fish finder, various measuring instruments, gauges (for example, gauges of a vehicle, an airplane, and a ship), a flight simulator, or the like.

Next, a moving object including the electronic device 1 will be described.

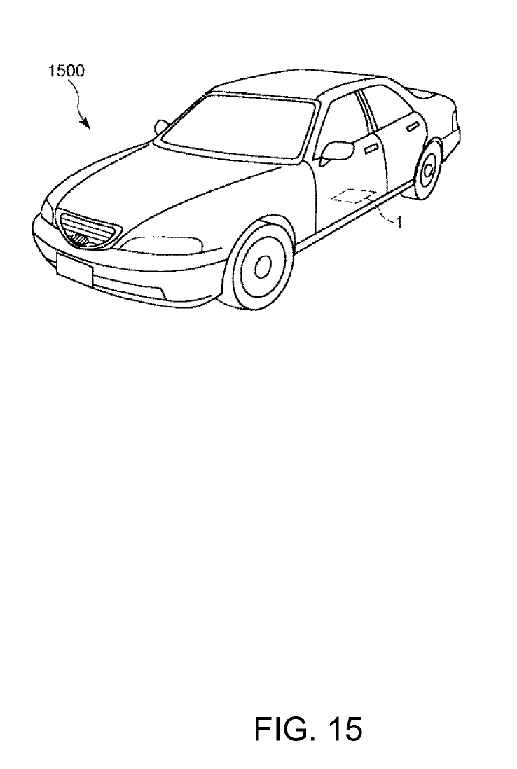

FIG. 15 is a perspective diagram illustrating a moving object including an electronic device according to the invention. The electronic device 1 is mounted on a vehicle (moving object) 1500. The electronic device 1 can be widely applied to an electronic control unit (ECU), such as a keyless entry, an immobilizer, a car navigation system, a car air conditioner, an anti-lock brake system (ABS), an airbag, a tire pressure monitoring system (TPMS), an engine control, a battery monitor of a hybrid vehicle or an electric vehicle, or a vehicle body posture control system.

As described above, a substrate for an electronic device package, an electronic device package, an electronic device, and a method of manufacturing the electronic device are described based on the illustrated embodiments, but the invention is not limited to these, and the configurations of the respective units can be replaced with an arbitrary configuration having the same function. In addition, another arbitrary configuration unit may be added to the invention. In addition, the respective embodiments may be appropriately combined.

In addition, a resonation element is contained in the embodiments described above as an electronic component, but the electronic component is not limited to the resonation element, and the electronic component may be, for example, various circuits (circuit substrate) such as an IC.

In addition, in the embodiments described above, in the base substrate, a wiring layer (external connection terminal) is disposed on a lower surface of the first layer, but another layer (for example, glass layer) may be interposed between the first layer and the wiring layer.

The entire disclosure of Japanese Patent Application Nos. 2014-117490, filed Jun. 6, 2014, and 2014-117491, filed Jun. 6, 2014 are expressly incorporated by reference herein.

What is claimed is:

1. A substrate for an electronic device package comprising:
a first layer that contains ceramic; and
a second layer that is disposed on one surface side of the first layer, contains at least one of glass, silicon, and quartz, as a material thereof, and has a concave portion which is opened on a side opposite to the first layer.

2. The substrate for an electronic device package according to claim 1, wherein the concave portion is formed by etching the second layer.

3. The substrate for an electronic device package according to claim 1, wherein the first layer includes a first wiring layer that is electrically connected to an electronic component.

4. The substrate for an electronic device package according to claim 3, further comprising:
a convex portion that is disposed inside the concave portion and is connected to the electronic component.

5. The substrate for an electronic device package according to claim 4, wherein the first wiring layer is disposed so as to extend to the convex portion.

6. The substrate for an electronic device package according to claim 1, wherein the first layer includes a plurality of ceramic layers.

7. The substrate for an electronic device package according to claim 6, wherein a second wiring layer is disposed between the plurality of ceramic layers and is electrically connected to the first wiring layer.

8. An electronic device package comprising:
the substrate for an electronic device package according to claim 1; and
a lid that is bonded to the substrate for an electronic device package so as to close an opening of the concave portion.

9. The electronic device package according to claim 8,
wherein the second layer includes glass, and
wherein the lid and the second layer are bonded together using glass fusion bonding.

10. The electronic device package according to claim 8, wherein the lid includes a lid side concave portion that is connected to the concave portion and is opened on a surface on the second layer side.

11. The electronic device package according to claim 10, wherein the lid side concave portion is formed through etching.

12. An electronic device comprising:
the electronic device package according to claim 8; and
an electronic component that is contained in the electronic device package.

13. A method of manufacturing an electronic device comprising:
preparing a base substrate that includes a first layer which contains ceramic, and a second layer which is disposed on one surface side of the first layer, contains at least one of glass, silicon, and quartz as a material thereof, and has a concave portion which is opened on a side opposite to the first layer;
disposing an electronic component inside the concave portion; and
bonding the lid to the base substrate so as to contain the electronic component together with the base substrate.

14. The method of manufacturing an electronic device according to claim 13, wherein the preparing of the base substrate includes forming the concave portion through etching.
